(19) United States
(12) Patent Application Publication
(10) Pub. No.: US 2015/0075603 A1
(43) Pub. Date: Mar. 19, 2015

(54) NOVEL HYDROPHOBIC COATINGS AND METHODS AND COMPOSITIONS RELATING THERETO

(71) Applicant: VITRIFLEX, INC., Milpitas, CA (US)

(72) Inventors: Mark Allen George, Tucson, AZ (US); Ching-Lin Chang, Milpitas, CA (US); Ravi Prasad, Corvallis, OR (US)

(21) Appl. No.: 14/385,770

(22) PCT Filed: Mar. 21, 2013
(86) PCT No.: PCT/US13/33392

§ 371 Date: Sep. 16, 2014

Related U.S. Application Data
(60) Provisional application No. 61/614,074, filed on Mar. 22, 2012.

(51) Int. Cl. G02B 1/10; A47J 36/02; C23C 16/40; C03C 17/245; H01L 31/0203; C04B 35/01

(52) U.S. Cl. CPC G02B 1/105; H01L 31/0203; C04B 35/01; C23C 16/40; C03C 17/245; A47J 36/02; C03C 2217/21; C03C 2218/153
USPC 136/256; 428/432; 428/702; 428/480; 428/473.5; 428/500; 428/421; 423/592.1; 423/593.1; 501/1; 423/326; 423/327.1; 423/598; 423/600; 423/594.8; 423/594.9; 423/594.14; 427/576

(57) ABSTRACT

A coating is described. The coating includes a metal oxide layer, which in turn includes a surface having a water contact angle greater than 90 degrees. A metal-oxide coating composition is also described. The composition includes effective amounts of a first type and a second of metals and an effective amount of oxygen to react with the first type and the second type of metals to produce a first type and a second type of metal oxides, both of which produce a structure that is greater than about 50% (by volume) amorphous.

### RELATED APPLICATION

This application claims priority from U.S. Provisional Application Ser. No. 61/614,074, which was filed on Mar. 22, 2012, and which is incorporated herein by reference for all purposes.

### FIELD

The present invention relates generally to novel hydrophobic coatings and methods and compositions relating thereto. More particularly, the present invention relates to metal oxide hydrophobic coatings and methods of making and compositions relating thereto.

### BACKGROUND

Many products, such as display devices, electronic devices, medical devices and pharmaceuticals, are sensitive to liquids, such as water, and exposure to them causes product deterioration and/or product performance degradation. Consequently, plastic coatings or layers are commonly used as a protective measure to safeguard against such undesired exposure.

Unfortunately, these coatings and layers suffer from durability, adhesion and performance degradation as they are easily scratched or abraded or removed from the surface entirely. As a result, these coatings are typically reapplied in order to retain surface performance. Moreover, this translates into higher maintenance cost for the current protective coatings.

What is therefore needed, are novel coating layer designs that do not suffer from the drawbacks encountered by conventional techniques of protecting underlying structures.

### SUMMARY

In view of the foregoing, in one aspect, the present teachings provide a coating layer. The coating layer includes a metal oxide layer that includes a surface having a water contact angle greater than 90 degrees.

In accordance with one exemplar structure of the present coating, the metal oxide layer is substantially free of voids. By way of example, the metal oxide layer is more than about 50% free of voids on a volume basis. Preferably, the metal oxide layer is more than about 85% free of voids on a volume basis, and more preferably, the metal oxide layer is more than about 95% free of voids on a volume basis.

The metal oxide layer may include a mixed-metal oxide. By way of example, the metal oxide layer includes a first type of metal oxide and a second type of metal oxide, and the first type of metal oxide is different from said second type of metal oxide. In another exemplar structure, the present coating further includes a third type of metal oxide and/or a fourth type of metal oxide. In this example, the third type of metal oxide and the fourth type of metal oxide are different from each other and are also different from the first and the second types of metal oxide.

Regardless of whether the third or the fourth types of metal oxide are present, the first and the second types of metal oxide composition are present in said metal oxide layer to form an amorphous metal oxide layer that is more than about 90% amorphous. In accordance with one embodiment of the present teachings, the first type of metal oxide has a concentration that is between about 5% by weight of the metal oxide layer and about 95% by weight of the metal oxide layer and the second type of metal oxide has a concentration that is between about 5% by weight of the metal oxide layer and about 95% by weight of the metal oxide layer. In a preferred embodiment of the present teachings, the first type of metal oxide has a concentration that is between about 20% by weight of the metal oxide layer and about 80% by weight of the metal oxide layer and the second type of metal oxide has a concentration that is between about 20% by weight of the metal oxide layer and about 80% by weight of the metal oxide layer. In a more preferred embodiment of the present teachings, the first type of metal oxide has a concentration that is between about 20% by weight of the metal oxide layer and about 60% by weight of the metal oxide layer and the second type of metal oxide has a concentration that is between about 20% by weight of the metal oxide layer and about 60% by weight of said metal oxide layer.

The first type of metal oxide may include a first type of metal and the second type of metal oxide may include a second type of metal, and oxygen is provided in the metal oxide layer in effective amounts to react with a substantial amount of the first and the second types of metal and produce the first and the second types of metal oxides. By way of example, oxygen is provided in the metal oxide layer in a range that is between about 10% and about 50% by weight of the metal oxide layer. The first type of metal oxide may include at least one metal chosen from a group comprising aluminum, silver, silicon, zinc, tin, titanium, tantalum, niobium, ruthenium, gallium, platinum, vanadium and indium. The second type of metal oxide may include at least one metal chosen from a group comprising aluminum, silver, silicon, zinc, tin, titanium, tantalum, niobium, ruthenium, gallium, platinum, vanadium and indium.

In one embodiment of the present teachings, the metal oxide layer is substantially amorphous. By way of example, the metal oxide layer is about 5% crystalline. The thickness of the metal oxide layer may be between about 20 nm and about 1 μm. The metal oxide layer is preferably substantially transparent. By way of example, the metal oxide layer transmits between about 70% and about 99% of the light incident upon it.

In another aspect, the present teachings provide a solar module. The solar module includes: (i) a solar cell; (ii) a transparent window; and (ii) a coating disposed adjacent to the transparent window, the coating comprising a metal oxide layer that includes a surface having a water contact angle greater than 90 degrees. The solar cell preferably includes at least one member chosen from a group comprising silicon, cadmium telluride, cigs, cis, organic photovoltaics and dye-sensitized solar cells.

In yet another aspect, the present teachings provide a display. The display includes: (i) a front glass; and (ii) a coating disposed adjacent to the front glass, such that the coating includes a metal oxide layer that includes a surface having a water contact angle greater than 90 degrees. The display includes one member chosen from a group comprising, for example, electrophoretic display, organic light emitting diode and liquid crystal display. The display is preferably touch-sensitive. The display may be used in a device chosen from a group comprising smartphone, computer tablet, computer monitor and television.

In yet another aspect, the present teachings provide a glass-based body. The glass-based body includes: a glass-based substrate; and a coating disposed adjacent to the glass-based substrate. The coating includes a metal oxide layer, which, in turn, includes a surface having a water contact angle greater than 90 degrees. The glass-based body may include a smart window or an insulated glass unit. The smart window preferably includes at least one member chosen from a group comprising electrochromic window, photochromic window and thermochromic window. The insulated glass unit preferably includes a skylight.

In yet another aspect, the present teachings provide a flexible object. The flexible object includes: (i) a flexible substrate; and (ii) a coating disposed adjacent to the flexible substrate. The coating includes a metal oxide layer, which, in turn, includes a surface having a water contact angle greater than 90 degrees. The flexible substrate includes at least one member chosen from a group comprising polyester, polyolefin, polyether-ether ketone, polyimide, polyvinyl chloride, polyvinyl alcohol and fluoropolymer.

In yet another aspect, the present teachings provide a cooking utensil. The cooking utensil includes: (i) a cooking surface; and (ii) a coating disposed adjacent to the cooking surface. The coating includes a metal oxide layer that includes a surface having a water contact angle greater than 90 degrees.

In yet another aspect, the present teachings provide a process of fabricating a coating. The process includes: (i) placing a metal oxide composition inside a chamber; (ii) introducing oxygen inside the chamber; (iii) striking a metal-oxide plasma inside the chamber to produce inside the chamber a metal oxide layer that includes a surface having a water contact angle greater than 90 degrees. The process further preferably includes providing a substrate inside the chamber and wherein striking includes striking the metal-oxide plasma inside the chamber to fabricate the metal oxide layer adjacent to the substrate. Striking the metal oxide plasma may involve at least one technique chosen from a group comprising sputtering, reactive sputtering, chemical vapor deposition and plasma-enhanced chemical vapor deposition. Striking the metal oxide plasma is preferably carried out at a temperature that is between about 10° C. and about 300° C. In preferred embodiments of the present teachings, striking the metal oxide plasma is carried out at a pressure that is between about 0.001 mTorr and about 30 mTorr.

In one embodiment, the present process of fabricating the coating further includes evacuating the chamber to create a substantial vacuum inside the chamber, and such evacuation may be carried out before introducing oxygen inside the chamber. The above-mentioned introducing may include introducing an inert gas inside the chamber.

In yet another aspect, the present teachings provide metal-oxide coating compositions. The metal-oxide coating compositions include: (i) an effective amount of a first type of metal; (ii) an effective amount of a second type of metal; (iii) an effective amount of oxygen to react with said first type and said second type of metal to produce a first type and a second type of metal oxides; and (iv) wherein said first type and said second type of metal oxides produce a structure that is greater than about 50% (by volume) amorphous. In preferred embodiments of the present compositions, each of the first type and the second type of metal oxides includes at least one member independently chosen from a group comprising aluminum, silver, silicon, zinc, tin, titanium, tantalum, niobium, ruthenium, gallium, platinum, vanadium and indium.

The construction of inventive coatings and methods of manufacturing and compositions relating thereto, however, and their advantages, are facilitated by accompanying figures and descriptions of exemplar embodiments.

### BRIEF DESCRIPTION OF THE DRAWINGS

FIG. 1A shows a perspective view of one exemplar inventive coating that is used for a wide variety of substrates.

FIG. 1B shows a perspective view of the coating shown in FIG. 1A having disposed thereon water droplets.

FIG. 2 shows a side-sectional view of a substrate having disposed thereon the coating and water droplets shown in FIG. 1B.

FIG. 3 is a top view of an exemplar machine used for manufacturing the coating shown in FIG. 1A.

FIG. 4 is a process flow diagram of an exemplar inventive method for making the coating shown in FIG. 1A.

### DETAILED DESCRIPTION

In the following description, numerous specific details are set forth in order to provide a thorough understanding of the present invention. It will be apparent, however, to one skilled in the art that the present invention may be practiced without limitation to some or all of these specific details. In other instances, certain well-known process steps have not been described in detail in order to not unnecessarily obscure the invention.

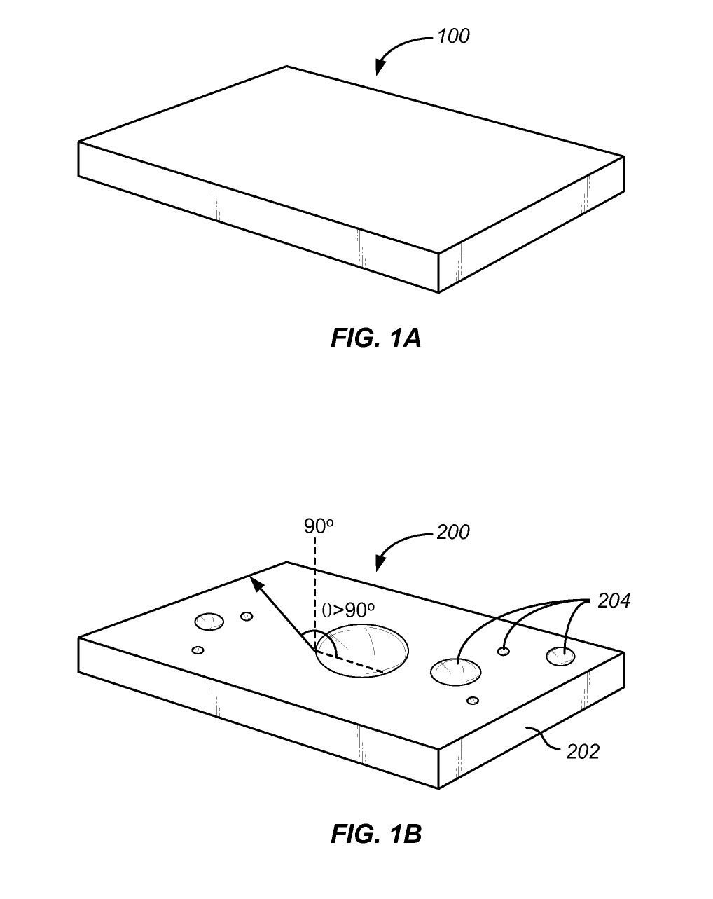

FIG. 1A shows a coating 100 according to one example of the present teachings. According to this exemplar teaching, coating 100 is a metal oxide layer that is substantially hydrophobic. In this aspect, water or water vapor contacting coating 100 do so at a contact angle that is greater than about 90 degrees. In preferred embodiments of the present teachings, coating 100 is dense and substantially void free. By way of example, coating 100 is more than about 50% free of voids on a volume basis, is preferably more than about 85% free of voids on a volume basis and more preferably, more than about 95% free of voids on a volume basis.

Coating 100 may be a mixed-metal oxide. By way of example, the mixed-metal oxide is a metal oxide alloy. The metal oxide alloy may include at least two different types of metal oxides, i.e., a first metal oxide and a second metal oxide. In one aspect, the first metal oxide is an oxide of one metal, which is chosen from a group comprising aluminum, silver, silicon, zinc, tin, titanium, tantalum, niobium, ruthenium, gallium, platinum, vanadium and indium. The second metal oxide is an oxide of another metal, which is chosen from a group comprising aluminum, silver, silicon, zinc, tin, titanium, tantalum, niobium, ruthenium, gallium, platinum, vanadium and indium. In other embodiments, coatings according to the present teachings include a third type and/or a fourth type of metal oxide. In this embodiment, the third and the fourth types of metal oxides are different from each other, and also different from the first and the second types of metal oxides.

According to one present teaching, the first and the second type of metal oxides are present in the metal oxide layer to form an amorphous metal oxide layer that is more than 90% amorphous. In one present arrangement, the first type of metal oxide, present in metal oxide of coating 100, has a concentration that is between about 5% by weight of the metal oxide and about 95% by weight of the metal oxide. In this arrangement, the second type of metal oxide, present in the metal oxide coating 100, has a concentration that is between about 5% by weight of the metal oxide and about 95% by weight of the metal oxide. In one preferred arrangement, however, each of the first type and the second type of metal oxides, present in metal oxide of coating 100, have a concentration that is between about 20% by weight of the metal oxide and about 80% by weight of the metal oxide. In a more preferred arrangement, each of the first type and the second type of metal oxides, present in metal oxide of coating 100, have a concentration that is between about 20% by weight of the metal oxide and about 60% by weight of the metal oxide.

In one aspect of the present teachings, the first type of metal oxide includes a first type of metal and the second type of metal oxide includes a second type of metal. In this aspect, oxygen is present, in the metal oxide of coating 100, in sufficient amounts to react with a substantial amount of the first type and the second type of metals to produce the first type of metal oxide and the second type of metal oxide, respectively. By way of example, in the metal oxide of coating 100, enough oxygen is present to react with between about 90% and about 100% of the first type and the second type of metals to produce the first type of metal oxide and the second type of metal oxide, respectively. In accordance with one embodiment of the present teachings, oxygen is present in the metal oxide layer, such as in coating 100, in an amount that is between about 10% by weight of the metal oxide layer and about 50% by weight of metal oxide layer. Examples of the different types of the first metal oxide and the second metal oxide so produced are listed above.

Metal oxide layer of coating 100 may be substantially amorphous. If coating 100 entirely comprises metal oxide, then the coating may be substantially amorphous. According to one present arrangement, metal oxide composition of coating 100 is about 5% crystalline.

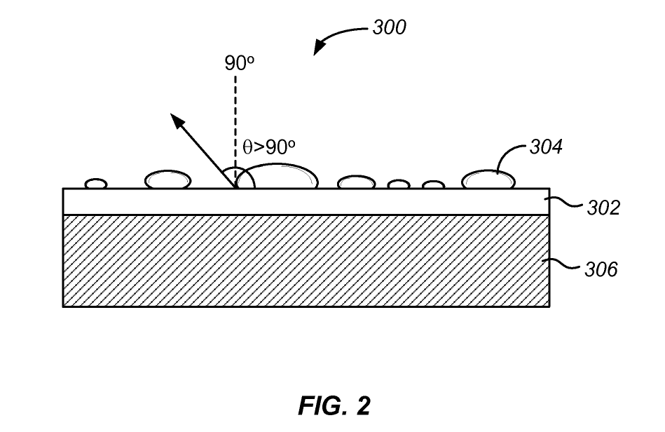

If the metal oxide composition is present in coating 100 in layer form, then metal oxide layer has a thickness that is between about 20 nm and about 1 μm. In one preferred embodiment of the present teachings, the metal oxide layer is substantially transparent for effective energy transmission to a structure underlying (e.g., layer 306 of FIG. 2) coating 100. By way of example, the metal oxide composition in coating 100 transmits between about 70% and about 99% of light incident upon the metal oxide layer to the structure underlying coating 100.

In accordance with a preferred embodiment of the present arrangement, coating 100 includes a metal oxide composition or layer having a surface with a liquid (e.g.,) water contact angle greater than 90 degrees.

FIG. 1B shows a present arrangement 200 comprising a coating 202 having disposed thereon one or more liquid (e.g., water) droplets 204. According to this figure, liquid droplets have contact angle that is greater than 90 degrees. A contact angle is the angle where the liquid/vapor interface meets a solid surface. The fact that the contact angle of liquid 204 with solid 202 is greater than 90 degrees may also convey that solid 202 is hydrophobic in nature.

FIG. 2 shows a side view of another present arrangement 300. According to this figure, liquid droplets 304 have a contact angle that is greater than 90 degrees when the liquid droplets contacts a (solid) coating 302 disposed above an underlying structure 306. Liquid droplets 304, and coating 302 are substantially similar to liquid 204 and coating 202. Underlying structure 306 may be of any type that requires protection from a liquid, such as water.

By way of example, present arrangement 300 of FIG. 2 includes one arrangement chosen from a group comprising solar module, display, glass-based body, flexible object and cooking utensil. For such arrangements, underlying structure 306 include one structure chosen from a group comprising solar cell, front glass, glass-based substrate, flexible substrate and cooking surface, respectively. Other examples of underlying structure 306 include eyeglasses, door hardware, door hinges, metal protection for bridges, metal used in structural applications, plumbing fixtures and mirrors used in bathrooms and in automotive.

In embodiments where underlying structure 306 include a solar cell, the solar cell preferably includes at least one member chosen from a group comprising silicon, cadmium telluride, cigs, cis, organic photovoltaics and dye-sensitized solar cells. In those instances where present arrangement 300 includes a display, the display includes at least one member selected from a group comprising electrophoretic display, organic light emitting diode and liquid crystal display. The display contemplated in one aspect of the present teachings is touch-sensitive. In other implementations of the present teachings, the display may be that is used in a smartphone, computer tablet, computer monitor and television.

In those embodiments where underlying structure 306 include a glass body, the glass body includes a smart window or an insulated glass (e.g., skylight). Smart window may include at least one member chosen from a group comprising electrochromic window, photochromic window and thermochromic window. If underlying structure 306 is a flexible substrate, then such flexible substrate includes at least one member chosen from a group comprising polyester, polyolefin, polyether-ether-ketone, polyimide, polyvinyl alcohol and fluoropolymer.

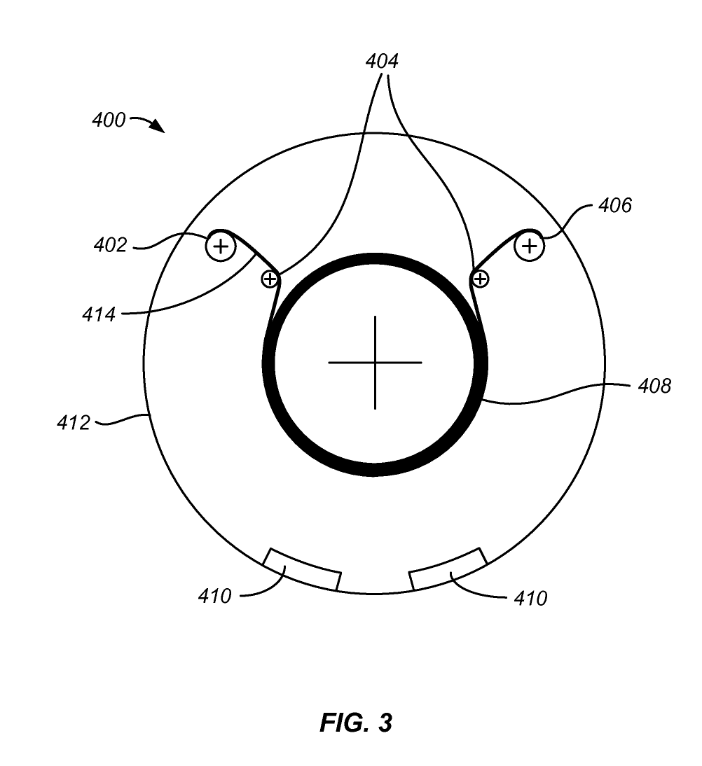

Although coatings of the present teachings (e.g., coating 100 of FIG. 1A, coating 202 of FIG. 1B and coating 300 of FIG. 3) may be made using any technique well known to those skilled in the art, using a roll-to-roll technique, which provides a relatively high throughput, represents a preferred embodiment of the present teachings. FIG. 3 shows a top view of a machine 400, according to one embodiment of the present teachings. Machine 400 may also be thought of as a “roll coater” as it coats a roll of a flexible material (e.g., underlying structure 306 of FIG. 2), which requires protection from a liquid, with a coating (e.g., coating 100 of FIG. 1, coating 202 of FIG. 1B and coating 302 of FIG. 2). Coating machine 400 includes an unwind roller 402, an idle roller 404, a take-up roller 406, a temperature controlled deposition drum 408, one or more deposition zones 410, and a chamber 412. Each of one or more deposition zones 410 include a target material, which is ultimately deposited on the flexible material, a power supply and shutters, as explained below.

A coating process, according to one embodiment of the present teachings, begins when a flexible material 414 is loaded onto unwind roller 402. Flexible material 414 is preferably wrapped around a spool that is loaded onto unwind roller 402. Typically a portion of the wrapped flexible material is pulled from the spool and guided around idle rollers 404 and deposition drum 408, which is capable of rotating, so that it connects to take-up roller 406. In the operating state of coating machine 400, unwind roller 402, take-up roller 406 and deposition drum 408 rotate, causing flexible material 414 to displace along various locations around cooled deposition drum 408.

Once flexible material 414 is loaded inside coating machine 400, the coating process includes striking plasma inside deposition zone 410. Shutters in the coating zones direct charged particles in the plasma field to collide with and eject the target material so that it is deposited on the flexible material. During the coating process, a temperature of flexible material 414 is controlled using deposition drum 408 preferably to values such that no damage is done to the material. In those embodiments of the present teachings where flexible substrate 414 includes a polymeric material, deposition drum 408 is cooled such that the temperature of the deposition drum is preferably near or below a glass transition temperature of the polymeric material. The cooling action prevents melting of, among other materials, the polymer-based material during the deposition process, and thereby avoids degradation of the polymer-based material that might occur in the absence of deposition drum 408.

As can be seen from FIG. 3, multiple deposition zones are provided, each of which may be dedicated to effect deposition of one particular material on the polymeric material. By way of example, the target material, in one of the deposition zones, includes at least one member chosen from a group comprising metal, metal oxide, metal nitride, metal oxy-nitride, metal carbo-nitride, and metal oxy-carbide to facilitate deposition of a coating (e.g., coating 100 of FIG. 1A, coating 202 of FIG. 1B and coating 300 of FIG. 3). By displacing flexible substrate 414 from one location to another, different types and different thicknesses of target material, at different deposition zones, may be deposited on the substrate. Coating machine 400 may be used to implement at least one technique chosen from a group comprising sputtering, reactive ion sputtering, evaporation, reactive evaporation, chemical vapor deposition and plasma-enhanced chemical vapor deposition.

It is noteworthy that instead of displacing the substrate from one position to another to facilitate deposition of one or more coatings, the inventive features of the present invention may be realized by holding the material (which is to be coated) stationary and displacing at least a portion of the coating machine or by displacing both the material and the coating machine.

Regardless of the specific process implemented for deposition, it will be appreciated that the roll-to-roll techniques of the present teachings allows for very rapid deposition of different types and thicknesses of layers on a material to deposit a protective coating thereon. The roll-to-roll fabrication processes of the present invention realize a very high throughput, which translates into increased revenue.

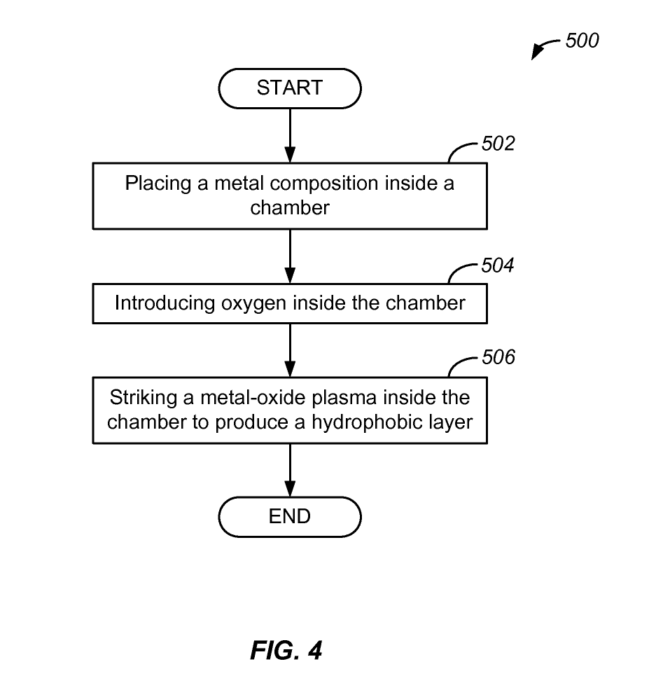

FIG. 4 shows a coating process 500 in accordance with one embodiment of the present teachings. Coating process 500 includes a step 502, which involves placing a metal composition inside a chamber (e.g., chamber 412 of FIG. 3). Next, in a step 504, oxygen is introduced inside the chamber. This is followed by a step 506, which includes striking metal-oxide plasma inside the chamber to produce a hydrophobic coating. The hydrophobic coating is preferably deposited on a flexible material as explained in connection with FIG. 3. The hydrophobic layer may be one that, when in contact with water, has a water contact angle greater than 90 degrees. In those instances where the material, which is to be coated, is not a flexible one, coating process may include at least one technique selected from a group comprising sputtering, reactive ion sputtering, evaporation, reactive evaporation, chemical vapor deposition and plasma-enhanced chemical vapor deposition.

The coatings according to the present teachings represent a marked improvement over the current techniques of protecting underlying structures, e.g., electronic devices, medical devices and pharmaceuticals. By way of example, external surfaces of the present coatings (e.g., coating 100 of FIG. 1A, coating 202 of FIG. 1B and coating 302 of FIG. 2) may be fabricated such that they are not susceptible to soiling (e.g., due to fingerprints) or accumulation of foreign contamination. As another example, coatings of the present teachings lend themselves to easy cleaning as they may be applied to an external surface for modifying its free surface energy. As yet another example, present coatings are durable as they have a high contact angle of greater than 90 degrees when they come in contact with liquids, such as water.

Although illustrative embodiments of the present teachings have been shown and described, other modifications, changes, and substitutions are intended. By way of example, the present teachings disclose coatings substantially impervious to liquids; however, it is also possible to reduce the transport of organic material using the systems, processes, and compositions of the present teachings. Accordingly, it is appropriate that the appended claims be construed broadly and in a manner consistent with the scope of the disclosure, as set forth in the following claims.

What is claimed is:

1. A coating comprising a metal oxide layer that includes a surface having a water contact angle greater than 90 degrees.

2. The coating of claim 1, wherein said metal oxide layer is substantially free of voids.

3. The coating of claim 2, wherein said metal oxide layer is more than about 50% free of voids on a volume basis.

4. The coating of claim 3, wherein said metal oxide layer is more than about 85% free of voids on a volume basis.

5. The coating of claim 4, wherein said metal oxide layer is more than about 95% free of voids on a volume basis.

6. The coating of claim 1, wherein said metal oxide layer includes a mixed-metal oxide.

7. The coating of claim 6, wherein said metal oxide layer includes a first type of metal oxide and a second type of metal oxide, and wherein said first type of metal oxide is different from said second type of metal oxide.

8. The coating of claim 7, further comprising a third type of metal oxide and/or a fourth type of metal oxide, wherein said third type of metal oxide and said fourth type of metal oxide are different from each other and are different from said first type of metal oxide and said second type of metal oxide.

9. The coating of claim 7, wherein said first and said second type of metal oxides are present in said metal oxide layer to form an amorphous metal oxide layer that is more than about 90% amorphous.

10. The coating of claim 7, wherein said first type of metal oxide has a concentration that is between about 5% by weight of said metal oxide layer and about 95% by weight of said metal oxide layer and said second type of metal oxide has a concentration that is between about 5% by weight of said metal oxide layer and about 95% by weight of said metal oxide layer.

11. The coating of claim 10, wherein said first type of metal oxide has a concentration that is between about 20% by weight of said metal oxide layer and about 80% by weight of said metal oxide layer and said second type of metal oxide has a concentration that is between about 20% by weight of said metal oxide layer and about 80% by weight of said metal oxide layer.

12. The coating of claim 11, wherein said first type of metal oxide has a concentration that is between about 20% by weight of said metal oxide layer and about 60% by weight of said metal oxide layer and said second type of metal oxide has a concentration that is between about 20% by weight of said metal oxide layer and about 60% by weight of said metal oxide layer.

13. The coating of claim 7, wherein said first type of metal oxide includes a first type of metal and said second type of metal oxide includes a second type of metal and oxygen is present in said metal oxide layer in effective amounts to react with a substantial amount of said first and said second types of metal and produce said first type and said second type of metal oxides.

14. The coating of claim 13, wherein oxygen is present in said metal oxide layer in an amount that is between about 10% by weight of said metal oxide layer and about 50% by weight of said metal oxide layer.

15. The coating of claim 7, wherein said first type of metal oxide includes at least one metal chosen from a group comprising aluminum, silver, silicon, zinc, tin, titanium, tantalum, niobium, ruthenium, gallium, platinum, vanadium and indium.

16. The coating of claim 7, wherein said second type of metal oxide includes at least one metal chosen from a group comprising aluminum, silver, silicon, zinc, tin, titanium, tantalum, niobium, ruthenium, gallium, platinum, vanadium and indium.

17. The coating of claim 1, wherein said metal oxide layer is about 5% crystalline.

18. The coating of claim 1, wherein a thickness of said metal oxide layer is between about 20 nm and about 1 μm.

19. The coating of claim 1, wherein said metal oxide layer is substantially transparent.

20. The coating of claim 1, wherein said metal oxide layer transmits between about 70% and about 99% of light incident upon said metal oxide layer.

21. A solar module comprising:
a solar cell;
a transparent window; and
a coating disposed adjacent to said transparent window, said coating comprising a metal oxide layer that includes a surface having a water contact angle greater than 90 degrees.

22. The solar module of claim 21, wherein said solar cell includes at least one member chosen from a group comprising silicon, cadmium telluride, cigs, cis, organic photovoltaics and dye-sensitized solar cells.

23. A display comprising:
a front glass; and
a coating disposed adjacent to said front glass, said coating including a metal oxide layer that includes a surface having a water contact angle greater than 90 degrees.

24. The display of claim 23, wherein said display includes one member chosen from a group comprising electrophoretic display, organic light emitting diode and liquid crystal display.

25. The display of claim 23, wherein said display is touch-sensitive.

26. The display of claim 23, wherein said display is used in a device chosen from a group comprising smartphone, computer tablet, computer monitor and television.

27. A glass-based body comprising:
a glass-based substrate; and
a coating disposed adjacent to said glass-based substrate, said coating including a metal oxide layer that includes a surface having a water contact angle greater than 90 degrees.

28. The glass-based body of claim 27, wherein said glass-based body includes a smart window or an insulated glass unit.

29. The glass body of claim 28, wherein said smart window includes at least one member chosen from a group comprising electrochromic window, photochromic window and thermochromic window.

30. The glass body of claim 28, wherein said insulated glass unit includes a skylight.

31. A flexible object comprising:
a flexible substrate; and
a coating disposed adjacent to said flexible substrate, said coating includes a metal oxide layer that includes a surface having a water contact angle greater than 90 degrees.

32. The flexible object of claim 31, wherein said flexible substrate includes at least one member chosen from a group comprising polyester, polyolefin, polyether-ether ketone, polyimide, polyvinyl chloride, polyvinyl alcohol and fluoropolymer.

33. A cooking utensil comprising:
a cooking surface; and
a coating disposed adjacent to said cooking surface, said coating includes a metal oxide layer that includes a surface having a water contact angle greater than 90 degrees.

34. A process of fabricating a coating, said process comprising:
placing a metal oxide composition inside a chamber;
introducing oxygen inside said chamber;
striking a metal-oxide plasma inside said chamber to produce a metal oxide layer that includes a surface having a water contact angle greater than 90 degrees.

35. The process of claim 35, further comprising providing a substrate inside said chamber and wherein said striking includes striking said metal-oxide plasma inside said chamber to fabricate said metal oxide layer adjacent to said substrate.

36. The process of claim 35, wherein said striking involves at least one technique chosen from a group comprising sputtering, reactive sputtering, chemical vapor deposition and plasma-enhanced chemical vapor deposition.

37. The process of claim 35, wherein said striking is carried out at a temperature that is between about 10° C. and about 300° C.

38. The process of claim 35, wherein said striking is carried out at a pressure that is between about 0.001 mTorr and about 30 mTorr.

39. The pressure of claim 35, further comprising evacuating said chamber to create a substantial vacuum inside said chamber, and said evacuating is carried out before said introducing.

40. The pressure of claim 35, wherein said introducing includes introducing an inert gas inside said chamber.

41. A metal-oxide coating composition comprising:
an effective amount of a first type of metal;
an effective amount of a second type of metal;
an effective amount of oxygen to react with said first type and said second type of metal to produce a first type and a second type of metal oxides; and
wherein said first type and said second type of metal oxides produce a structure that is greater than about 50% (by volume) amorphous.

42. The metal-oxide coating composition of claim 41, wherein each of said first type and said second type of metals includes at least one member independently chosen from a group comprising aluminum, silver, silicon, zinc, tin, titanium, tantalum, niobium, ruthenium, gallium, platinum, vanadium and indium.
